(19) United States
(12) Patent Application Publication
(10) Pub. No.: US 2019/0353691 A1
(43) Pub. Date: Nov. 21, 2019

(54) ELECTRICITY SUBMETER

(71) Applicant: Embertec Pty Ltd, Dulwich (AU)

(72) Inventor: Riccardo Gatto, Dulwich (AU)

(21) Appl. No.: 16/045,917

(22) Filed: Jul. 26, 2018

(30) Foreign Application Priority Data
May 15, 2018 (AU) 2018203426

(51) Int. Cl. G01R 21/133; G08C 23/04; H04Q 9/02

(52) U.S. Cl. CPC G01R 21/1331; H04Q 2213/13204; H04Q 9/02; G08C 23/04

(57) ABSTRACT

A submeter for measuring electricity use collects information usage data from several sensors, such as circuit clamps which each measure usage within an individual circuit within a premises. The submeter is programmed for operation using an installation tool wherein an installer can enter configuration data defining the characteristics of each circuit (e.g., air conditioner circuit, swimming pool circuit, etc.), and transmit the configuration data to the submeter. The submeter can then transmit electricity usage data from the circuits, along with the configuration data, to an Intelligent Power Manager or other processor which can analyze and/or display energy usage among the various circuits.

### FIELD OF THE INVENTION

The present invention relates to the field metering of electricity usage, in particular for energy demand management and control of energy demand.

### BACKGROUND OF THE INVENTION

Increasing electricity prices and environmental concerns have led to greater interest on the part of electricity consumers in reducing electricity consumption in general, and reducing reliance on expensive electricity from the public grid in particular.

There have been considerable efforts directed toward energy efficiency measures, both reducing electricity consumption, and directing consumption away from peak grid demand times.

There has also been considerable installation of behind-the-meter electricity generation and storage, including solar photo-voltaic generation and battery storage.

For optimum efficiency, these measures are best implemented with effective, real time monitoring of electricity usage, storage and generation occurring within the premises.

Electricity usage is generally measured by a meter placed in the premises where consumption occurs. These meters are provided by the utility supplying the electricity to the premises, and are designed to be read primarily by the utility. The meter may be an analog meter which is only able to be read visually.

More recently, digital electronic meters have been provided which may be read electronically, outputting readings as a data stream. However, these meters are still largely intended to be read only by the supply utility. In general, the utility cannot or will not supply real time output data from such meters to the electricity consumer in the premises.

This has led to the consumer installation of “submeters” which enable measurement of electricity usage and generation. Such submeters may measure a number of components of electricity usage, storage and generation across different electrical circuits, major appliances, solar PV and batteries.

These submeters may be associated with home energy management systems which analyze electricity usage and direct energy efficiency measures. Where there are numerous elements to measure, installation of the submeter and configuration of the energy management system may be complex.

### SUMMARY OF THE INVENTION

An exemplary version of the invention involves a submeter for measuring electricity use, the submeter including digital memory adapted to store configuration data describing the installation of the submeter, and further including communication means adapted to receive the configuration data for storage in the digital memory, and to transmit the configuration data retrieved from the digital memory.

The communication means preferably includes a first communication interface adapted to receive the configuration data and a second communication interface adapted to transmit the configuration data.

The first communication interface and the second communication interface may use the same communication protocol, or different protocols.

One or both of the first communication interface and the second communication interface are preferably adapted to communicate with the public internet.

Preferably, the first communication interface is an IrDA interface and the second communication interface is a ZigBee interface.

The submeter may further include an installation tool having a user interface adapted to permit a user to input the configuration data to be received by the submeter and a tool communication interface able to communicate with the communication means.

The installation tool may include a tool communication interface adapted to communicate with the first communication interface to communicate the configuration data to be received by the submeter.

The invention also involves an installation tool for use with the submeter including a user interface adapted to permit a user to input the configuration data to be received by the submeter and a tool communication interface able to communicate with the communication means.

The invention also involves a system for installation of an energy usage monitoring device, the system including a submeter for measuring electricity use including digital memory adapted to store configuration data describing the installation of the submeter and communication means adapted to receive the configuration data for storage in the digital memory and to transmit the configuration data retrieved from the digital memory, wherein the energy usage monitoring device is adapted to receive the configuration data from the communication means.

The system preferably includes an installation tool having a user interface adapted to permit a user to input the configuration data to be received by the submeter and a tool communication interface able to communicate with the communication means.

The communication means preferably includes a first communication interface adapted to receive the configuration data and a second communication interface adapted to transmit the configuration data, the first communication interface being adapted to receive the configuration data from the tool communication interface and the second communication interface being adapted to transmit the configuration data to the energy usage monitoring device.

Further advantages, features, and objects of the invention will be apparent from the remainder of this document in conjunction with the associated drawings.

### BRIEF DESCRIPTION OF THE DRAWINGS

FIG. 1 is a block diagram representation of a submeter exemplifying the invention.

FIG. 2 is a block diagram of an exemplary energy usage monitoring system incorporating the invention.

FIG. 3 is a diagrammatic representation of an exemplary installation tool of the invention.

FIG. 4 illustrates an exemplary input screen of the installation tool of FIG. 3.

FIG. 5 illustrates an exemplary output screen of the installation tool of FIG. 3.

### DETAILED DESCRIPTION OF EXEMPLARY VERSIONS OF THE INVENTION

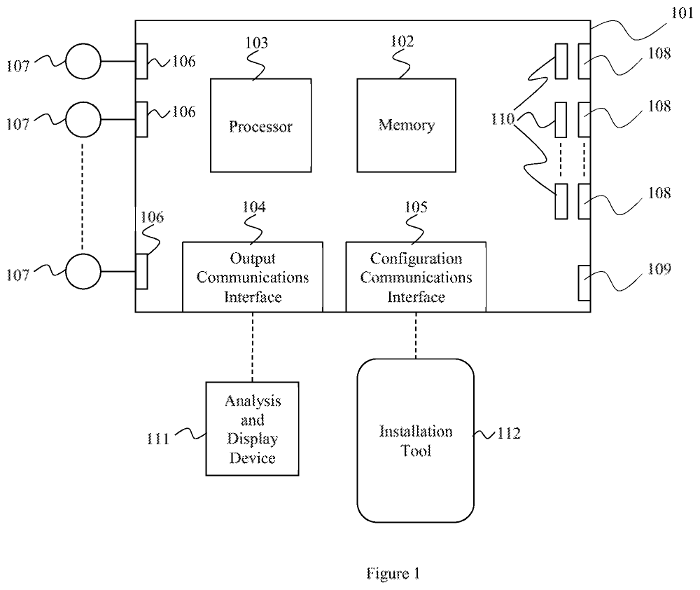

Looking to the accompanying drawings, FIG. 1 depicts a block diagram representation of an exemplary version of an electricity submeter incorporating features of the invention.

A submeter 101 is installed in a premises having an electricity supply from a grid. The submeter 101 includes memory 102 and a processor 103. The submeter 101 also includes a communication means for receiving configuration data for the submeter 101 and sending submeter 101 measurement and other data, the communication means here being provided by a Configuration Communications Interface 105 and an Output Communications Interface 104.

The submeter 101 also includes at least one current sensor electrical connection point 106 which allows the electrical connection of at least one current sensor, here a current clamp 107. An active connector 108 is also provided for connection to the active conductor of the electricity supply associated with the current clamp 107, and a neutral connector 109 for connection to the neutral point of the electricity supply. The submeter 101 also includes a voltage sensor 110 in electrical connection with the active connector 108 and the neutral connector 109, allowing for the measurement of the voltage of the electrical supply associated with the measured current.

The current clamp 107 is device which encircles an electrical conductor and measures the current flowing therein by the transformer effect. The current clamp 107 provides an electrical signal which is proportional to the current flowing in the conductor around which it is installed.

The processor 103 receives the electrical signal from the current clamp 107 and the output of the voltage sensor 110. The processor uses these inputs to calculate the power being used by the circuit, the conductor of which is surrounded by the clamp 107.

The processor 103 communicates the calculated circuit power to an external analysis and display device 111 via the Output Communications Interface 104.

Multiple current clamps 107 will typically be provided, each with an associated active connector 108 and voltage sensor 110. These may be connected to measure current in a variety of circuits, supplying electricity to a variety of household appliances. This allows for power usage of each of these circuits to be monitored. Data describing the power in each of the circuits is displayed by the analysis and display device 111.

In order for the data displayed by the analysis and display device 111 to be useful, it is necessary for the analysis and display device 111 to have configuration data describing the usage of each monitored circuit. Where this information is provided to the analysis and display device 111 by a process which is independent of the installation of the submeter 101, there is increased opportunity for errors wherein the configuration data provided to the analysis and display device 111 regarding the installation of the current clamps 107, or the use of the respective circuits, is not accurate.

The configuration data is preferably provided by the installer of the submeter 101, typically a qualified electrician. However, the analysis and display device 111 may be secured for use only by the premises occupier, or may require additional setup parameters to be entered, unrelated to the configuration data. The analysis and display device 111 may be located remotely from the submeter 101. An electrician must be paid at a relatively high hourly rate for any work undertaken, including entry of configuration data. It may thus be uneconomic or inconvenient for the installer to directly enter configuration data into the analysis and display device 111.

An installation tool 112 communicates with the submeter 101 via the Configuration Communications Interface 105.

The installation tool 112 is used by the installer to input the description of the circuit associated with each of the current clamps 107. This configuration data is communicated to the submeter 101 via the Configuration Communications Interface 105. The configuration data is stored in the memory 102.

This configuration data is then made available to the analysis and display device 111. This configures the analysis and display device 111 with data describing the function of the circuit monitored by each of the current clamps 107. The analysis and display device 111 displays the data collected by each current clamp 107 with appropriate description. The analysis and display device 111 uses the configuration data to analyze the power usage data of the current clamps 107 transmitted by the processor 103 appropriately for the function of the circuit monitored by the respective clamp 107.

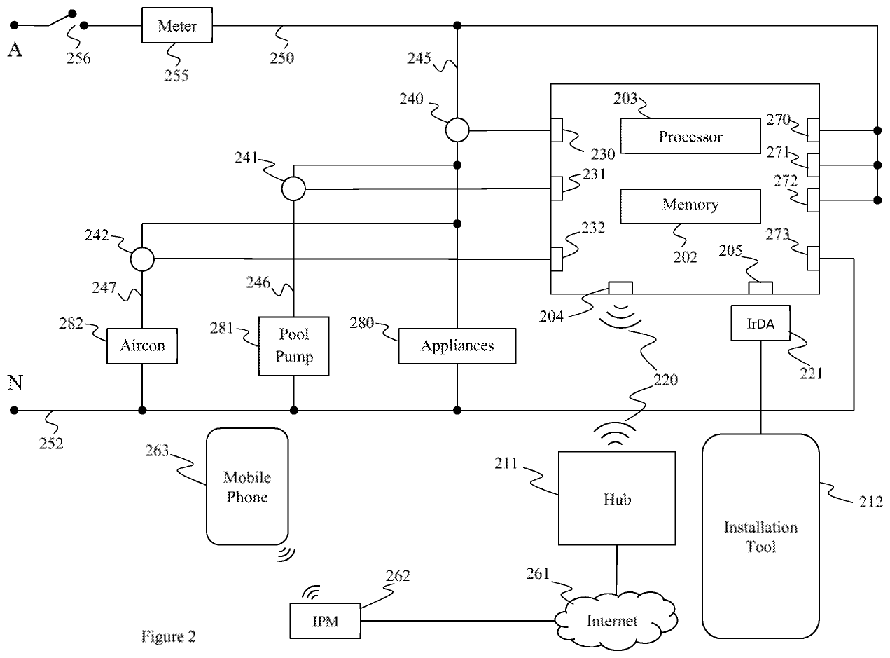

FIG. 2 depicts a block diagram of an energy usage monitoring system for a household, wherein a grid electricity supply has an active conductor 250 and a neutral conductor 252. A main switchboard meter 255 measures electricity supplied to the household for the purposes of billing by the grid supplier. A main switch 256 allows the household circuits to be isolated from the grid supply.

The grid supply provides electricity for the electrical loads of the household, including air conditioner 282, pool pump 281 and general lighting and appliances load 280.

A submeter 201 installed in the household includes processor 203 and memory 202. The submeter 201 further includes communication means for receiving configuration data for the submeter 201 and sending submeter 201 measurement and other data, the communication means here being provided by a Configuration Communications Interface 205 and an Output Communications Interface 204.

The submeter 201 monitors the electrical power in at least some electrical circuits supplying electrical loads in the household. This requires measurement of the voltage and current in each monitored circuit.

The total power supplied to the household from the grid flows through circuit 245. The current flowing in this circuit 245 is monitored by current clamp 240 which is installed around the conductor of the circuit 245. Voltage clamp 240 is connected to the submeter 201 via current sensor electrical connection point 230. The voltage is monitored by a connection of the active conductor 250 to active connector 270. Signals from the current clamp 240 and the active connector 270 are applied to the processor 203. The processor analyzes these signals to calculate the power flowing to the entire household via circuit 245.

The submeter 201 may also determine the power flowing in subcircuits which supply electricity to individual loads in the premises. Subcircuit 246 supplies electricity to pool pump 281. This subcircuit branches off from the main circuit 245 after the point at which current clamp 240 is attached to the main circuit 245. The current flowing in subcircuit 246 is monitored by current clamp 241. The voltage is monitored by a connection of the active conductor 250 to active connector 271. Signals from the current clamp 241 and the active connector 271 are applied to the processor 203. The processor analyzes these signals to calculate the power flowing in subcircuit 246, and hence the energy consumption of the pool pump 281.

Subcircuit 247 supplies electricity to air conditioner 282. Again, this subcircuit 247 branches off from the main circuit 245 after the point at which current clamp 240 is attached to the main circuit 245, and is a separate subcircuit from the subcircuit 246 feeding the pool pump. The current flowing in subcircuit 247 is monitored by current clamp 242. The voltage is monitored by a connection of the active conductor 250 to active connector 272. Signals from the current clamp 242 and the active connector 272 are applied to the processor 203. The processor analyzes these signals to calculate the power flowing in subcircuit 247, and hence the energy consumption of the air conditioner 282.

An analysis and display hub device (hub) 211 may be provided, with functionality ranging from simple display of the power measurements made by the submeter 201 up to sophisticated home energy hub functionality, including control of appliances.

The hub 211 is in data communication with the submeter 201 using output communication channel 220 via Output Communications Interface 204. Processor 203 calculates the power in each monitored circuit and communicates this data to the hub 211 using output communication channel 220 via Output Communications Interface 204.

The Output Communications Interface 204 may use any convenient data communication interface (transceiver, bus, etc.) and data transmission protocol, including without limitation, Zigbee, wi-fi, and wired ethernet connections. The Configuration Communications Interface 205 may similarly use any convenient interface or protocol, with a particularly preferred IrDA interface being discussed below.

The hub 211 has a connection to an Intelligent Power Manager (IPM) 262 serving as an external processor, with this connection being provided in FIG. 2 by the public internet 261.

The Intelligent Power Manager (IPM) 262 is a remote computer processor which is in communication with one or more hubs situated in one or more households. Data from the submeter 201 is transmitted via the hub 211 and the internet connection 261 to the IPM 262. The IPM 262 is able to record and analyze data on electricity consumption from one or more households.

An internet access device 263 (which may be, without limitation, a mobile phone or a personal computer), provides a user interface for the Intelligent Power Manager (IPM) 262, for example by running an internet browser which displays a user interface from the IPM 262. Alternatively, the internet access device 263 may run an App which provides the user interface locally, to display information from the IPM 262.

The Intelligent Power Manager (IPM) 262 also records, where available, information regarding the make-up of the households, the appliances in each household, and the geographic location of each household.

The Intelligent Power Manager (IPM) 262 monitors and tracks the energy usage patterns of a particular household and compares this data to similar sized homes, preferably in real time or at intervals significantly less than the household electricity billing interval, to provide the basis for householders to compare their energy usage with that of others during particular time periods.

Data from the household which is useful to profile the energy usage of the household, such as energy usage and other data concerning household make-up, is encrypted and stored in the Intelligent Power Manager (IPM) 262.

The householder can then access their energy usage information from the Intelligent Power Manager (IPM) 262 via the internet access device 263 at any time to assess their energy usage over certain time periods, i.e. over the last hour, 24 hours, week, or month, as desired. The information is displayed by the user interface on the internet access device 263.

The Intelligent Power Manager (IPM) 262 provides information concerning cost and budget to the household via the internet access device 263. This requires that the IPM 262 have access to the tariff rate applicable to the household. Tariffs may not be constant over the day, week, month or any other time period. The applicable tariff details may be entered by a householder, or the details of the tariff may be acquired by the IPM 262 from an energy retailer supplying energy to the household.

Via the user interface of the internet access device 263, the householder can enter household description data, which describes the makeup of the household, details of the dwelling, and information about the appliances in use in the household.

In order for the information displayed on the internet access device 263 to be meaningful, information describing the way in which the submeter 201 has been wired must be communicated to the Intelligent Power Manager (IPM) 262. It is advantageous if the installation of the submeter 201 can be achieved by an electrician or other installer, without the need to interact with any user interfaces provided by the IPM 262 and the internet access device 263, since these interfaces are optimized for ongoing household user use. Such interaction adds complexity which is unnecessary for the installer and the installation process.

An installation tool 212 communicates with the submeter 201 via the Configuration Communications Interface 205. The installation tool 212 includes a meter communication interface 221, preferably an IrDA interface, which communicates with the Configuration Communications Interface 205. This interface uses infra-red radiation to provide a communication channel which is short range and line of sight, making for a very simple, reasonably secure communication channel. IrDA has the advantage that it is a wireless channel providing electrical separation between the submeter 201 and the installation tool 212. Being line of sight and short range, IrDA provides physical security for the channel, meaning that encryption and log-in protection is not required. Alternatively, any convenient wired or wireless protocol may be employed.

The installation tool 212 is used by the installer to input the description of the circuits associated with each of the clamps 240, 241 and 242. This configuration data is communicated to the submeter 201 via the Configuration Communications Interface 205. The configuration data is stored in memory 202.

The submeter 201 communicates the power measurement calculated for each circuit 245, 246, 247 to the installation tool 212. The installation tool 212 is able to display these measurement results, along with the identity of each circuit as provided in the configuration data, for each circuit being monitored.

The submeter 201 can be monitored at installation without the need for the hub 211 to be present. This is advantageous because it allows the installation of the submeter 201 and the provision of the hub 211 to proceed independently.

During installation, the installer installs the submeter 201 and places current clamps around selected circuits. In FIG. 2, these circuits are the Whole House circuit 245 supplying electricity to all loads in the household, the Pool circuit 246 supplying electricity to the swimming pool pump, and the Air-Conditioning circuit 247 supplying electricity to an air-conditioning unit. Other loads which may have a supply circuit include, without limitation, hot water heaters and in-floor heating. Where a solar PV installation exists within the household, the electrical supply circuit from this installation may be monitored (thereby monitoring generation rather than consumption of electricity). A circuit supplying a storage battery may also be monitored, thereby monitoring energy flows into and out of the battery.

During installation the hub 211 may not be configured, or may be absent. Configuration of the hub 211, or of the IPM 262 via the hub 211, may be impossible or inconvenient for the installer.

During installation, the installer uses the installation tool 212 to enter data describing which clamps have been applied to which circuits and the function of the loads supplied by those circuits. This data is transmitted to the submeter 201 via the IrDA interface 221 of the installation tool 212 and the Configuration Communications Interface 205 of the submeter 201. This configuration data is stored in the memory 202. Configuration data may include data which identifies the particular installation tool and/or the particular installer. General information including, without limitation, the date of installation, the company providing the installation, the GPS coordinates of the installation tool at the time of the installation, and any other data to identify the installer and the installation circumstances, may also be stored into the memory 202 by the installation tool. The processor 203 of the submeter 201 may also directly store information concerning the installation, for example the date and time, into the memory 202.

When the hub unit 211 is available, the hub unit 211 and the submeter processor 203 establish the wireless output communication channel 220. The configuration data can then be downloaded from memory 202 using output communication channel 220 via Output Communications Interface 204 to the hub unit 211. The configuration data is then transmitted to the IPM 262 via the internet 261. The IPM 262 uses this configuration data in order to categorize the electricity flow data received from the submeter 201. The IPM can then analyze the electricity flow data with the information describing the use of each monitored circuit.

The IPM 262 can then display correctly described and analyzed data on the internet access device 263, in the illustrated version, a mobile phone.

The submeter is preferably provided with multiple active connectors. Each active connector is associated with a respective current sensor electrical connection point. The current clamp connected to that current sensor electrical connection point is deployed to measure the current in a circuit supplied from the associated active conductor. This ensures that the correct voltage reference is used for each measured circuit. It also allows for use in a premises supplied with two or three phase electricity. In such an installation, there will be multiple active conductors coming into the premises from the supply grid, one for each phase. Any one active conductor supplying any phase can be connected to any active connector. The current clamp connected to the associated current sensor electrical connection point is deployed to measure the current in a circuit supplied by the phase of the associated active conductor. This allows for the measurement of the power consumed by devices which are powered by circuits connected to any of the phases.

The illustrated versions of the submeters show the current sensors as current clamps. Other current sensing technologies may be used, including, without limitation, Hall effect devices and current shunts.

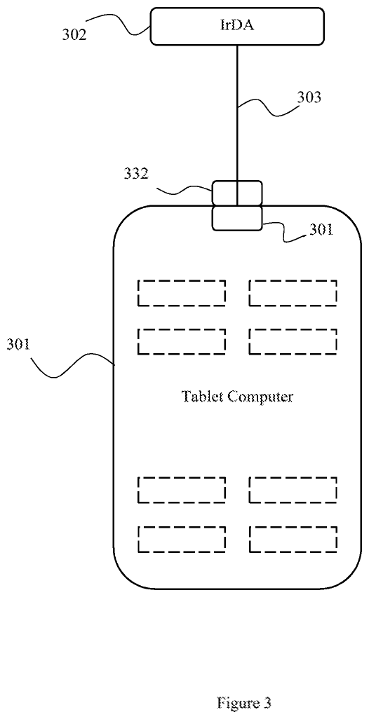

FIG. 3 shows an exemplary installation tool for use in configuring an electricity usage monitoring installation. A tablet computer 301 provides processing and display functionality for the installation tool. The tablet computer 301 runs software to implement the functionality of the installation tool.

The tablet computer 301 includes a data connector, shown in FIG. 3 as a USB connector 331. Other suitable data connectors may be provided.

A meter communication interface unit 302 is provided for communication with an electricity usage monitoring meter. In FIG. 3, the interface unit 302 is an IrDA protocol interface, providing short range wireless communication using infra-red signals. Other suitable wired or wireless connections may be employed.

The interface unit 302 includes data cable 303 and cable connector 332. The cable connector connects to the data connector 331 of the tablet computer 301 to provide data connection to the IrDA interface 302.

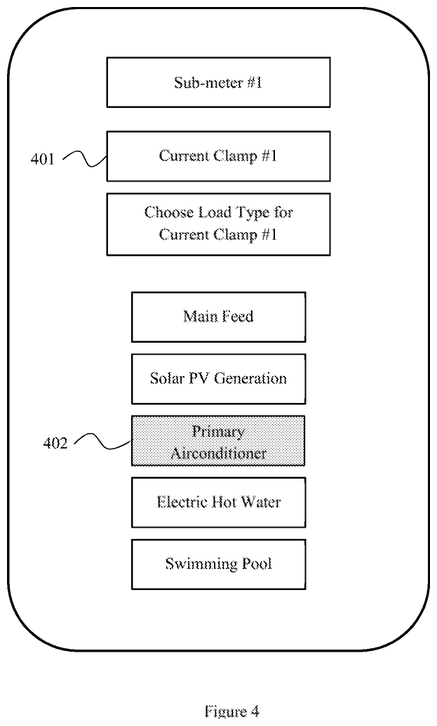

FIG. 4 shows a diagram of an exemplary input screen of the installation tool of FIG. 3. The input screen allows an installer to nominate the use of each current clamp in a submeter installation. For each current clamp 401, the installer may choose from a list of available load descriptions 402. This description is then sent to the submeter as configuration data, to be recorded in memory by the submeter.

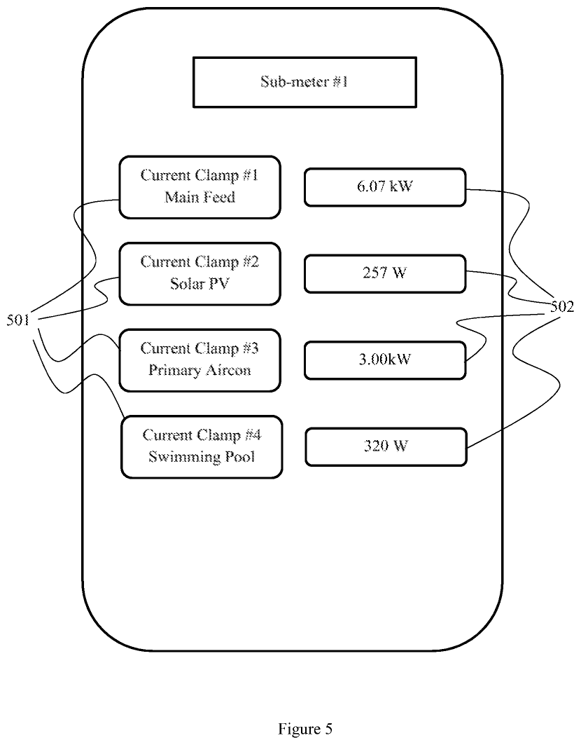

FIG. 5 shows an exemplary output display of the installation tool of FIG. 3. The installation tool receives data from the submeter showing the description 501 recorded by the submeter for the load which each current clamp is measuring. The current power measurement 502 for that load is displayed. This permits an installer to check that an installation has been performed correctly, without the need for a hub device and/or an IPM to be available at the time of installation.

The installation tool may alternatively be provided as a purpose-built display and processing unit, implementing the described functions of the installation tool via hardware or firmware.

The IPM need not be provided in the foregoing arrangements, with the functionality of the IPM being provided by the hub 211.

It should be understood that the versions of the invention described above are merely exemplary, and the invention is not intended to be limited to these versions. Rather, the scope of rights to the invention is limited only by the claims set out below, and the invention encompasses all different versions that fall literally or equivalently within the scope of these claims.

What is claimed is:

1. A submeter for measuring electricity use, the submeter including:
a. a digital memory configured to store configuration data defining the installation of the submeter, and
b. a communication means for:
(1) receiving the configuration data for storage in the digital memory, and
(2) transmitting data retrieved from the digital memory, the transmitted data including operational data characterizing measurements collected by the submeter during post-installation operation of the submeter.

2. The submeter of claim 1 wherein the transmitted data further includes at least some of the configuration data.

3. The submeter of claim 1 wherein:
a. the submeter is in connection with several sensors, each sensor being associated with a separate circuit, and
b. the configuration data defines characteristics of each separate circuit.

4. The submeter of claim 3 wherein the sensors include current clamps.

5. The submeter of claim 3 wherein the communication means includes:
a. a first communication interface configured to receive the configuration data, the first communication interface including an IrDA interface; and
b. a second communication interface configured to transmit the transmitted data.

6. The submeter of claim 5 wherein the transmitted data further includes at least some of the configuration data.

7. The submeter of claim 5 in combination with a submeter installation tool, the submeter installation tool having:
a. a user interface configured to permit a user to input the configuration data to be received by the submeter, and
b. a tool communication interface configured to communicate the configuration data to the communication means.

8. The submeter of claim 5 in combination with a hub configured to:
a. receive the transmitted data from the second communication interface, and
b. relay the transmitted data to an Intelligent Power Manager.

9. The submeter of claim 8 further in combination with an energy usage monitoring device, the energy usage monitoring device being one of:
a. a smartphone, or
b. a personal computer,
configured to receive processed data from the Intelligent Power Manager, the processed data being dependent on the transmitted data.

10. The submeter of claim 9 wherein the transmitted data further includes at least some of the configuration data.

11. The submeter of claim 1 wherein the communication means includes:
a. a first communication interface configured to receive the configuration data, and
b. a second communication interface configured to transmit the transmitted data,
wherein the first communication interface and the second communication interface use different data communication protocols.

12. The submeter of claim 1 wherein the communication means includes:
a. a first communication interface configured to receive the configuration data, and
b. a second communication interface configured to transmit the transmitted data,
wherein one or both of the first communication interface and the second communication interface are configured to communicate with the public internet.

13. The submeter of claim 1 wherein the communication means includes:
a. a first communication interface configured to receive the configuration data, the first communication interface including an IrDA interface; and
b. a second communication interface configured to transmit the transmitted data.

14. The submeter of claim 13 wherein the second communication interface includes a ZigBee interface.

15. The submeter of claim 1 in combination with a submeter installation tool, the submeter installation tool having:
a. a user interface configured to permit a user to input the configuration data to be received by the submeter, and
b. a tool communication interface configured to communicate the configuration data to the communication means.

16. The submeter of claim 15 wherein the communication means includes:
a. a first communication interface configured to receive the configuration data, and
b. a second communication interface configured to transmit the transmitted data, and wherein the submeter installation tool includes a tool communication interface configured to communicate the configuration data to the first communication interface.

17. A system for installation of an energy usage monitoring device, the system including:
a. a submeter for measuring electricity use, the submeter including:
(1) a digital memory configured to store configuration data describing the installation of the submeter, and
(2) a communication means for:
(a) receiving the configuration data for storage in the digital memory, and
(b) transmitting configuration data retrieved from the digital memory; and
b. an energy usage monitoring device configured to receive the configuration data from the communication means.

18. The system of claim 17 further including a submeter installation tool, the submeter installation tool including:
a. a user interface configured to permit a user to input the configuration data to be received by the submeter, and
b. a tool communication interface configured to communicate the configuration data to the communication means.

19. The system of claim 18 wherein the communication means includes:
a. a first communication interface configured to receive the configuration data from the tool communication interface, the first communication interface including an IrDA interface; and
b. a second communication interface configured to transmit the transmitted data to the energy usage monitoring device.
